(19) United States
(12) Patent Application Publication
(10) Pub. No.: US 2026/0371940 A1
(43) Pub. Date: Nov. 19, 2026

(54) Superconducting device

(71) Applicant: Teknologian tutkimuskeskus VTT Oy, Espoo (FI)

(72) Inventor: Jukka-Pekka Kaikkonen, Espoo (FI)

(21) Appl. No.: 19/486,985

(22) PCT Filed: May 21, 2024
(86) PCT No.: PCT/FI2024/050246

§ 371 Date: Nov. 24, 2025

(30) Foreign Application Priority Data
May 24, 2023 (FI) 20235579

(51) Int. Cl. H10N 60/80; G06N 10/40; H10N 60/12; H10N 60/81; H10N 60/82; H10N 60/85; H10N 69/00

(52) U.S. Cl. CPC H10N 60/805; G06N 10/40; H10N 60/12; H10N 60/815; H10N 60/82; H10N 60/855; H10N 69/00

(57) ABSTRACT

According to an example aspect of the present invention, there is provided a superconducting device comprising a silicon substrate (101), a superconducting layer (110) directly on a first face of the silicon substrate, the superconducting layer covering a part, but not all, of the first face of the silicon substrate, and a silicon nitride layer (107, 109) directly covering at least one part of the first face of the silicon substrate which is not covered by the superconducting layer.

### FIELD

The present disclosure relates to reducing microwave losses in superconducting devices.

### BACKGROUND

Silicon and metal surfaces are common in many silicon-based devices used in technical applications in the field of electrical engineering and electronics, such as superconducting devices. Different applications set different requirements on technical characteristics of such surfaces and structures, wherein quantum computing applications lie at the extreme end of the spectrum in terms of requiring extremely high-quality surfaces with a minimal density of defects capable of absorbing energy from fragile quantum systems, such as quantum bits, qubits. In particular, amorphous oxide layers that form naturally on both silicon and metal surfaces contain parasitic two-level systems that may limit the performance of state-of-the-art superconducting devices, such as qubits.

One feature of silicon and metal surfaces which is of interest is the tendency of such surfaces to grow, in regular atmospheric conditions, an oxide layer thereon. This native oxide layer, which may be a few nanometres thick, may be a limiting factor in certain applications. While the oxide layer may be removed, for example by chemical etching, it has a tendency to re-grow to a similar thickness as before, wherefore its removal tends to be futile in terms of permanently enhancing performance of devices which suffer from the presence of a native oxide layer.

### SUMMARY

According to some aspects, there is provided the subject-matter of the independent claims. Some embodiments are defined in the dependent claims.

According to a first aspect of the present disclosure, there is provided a superconducting device comprising a silicon substrate, a superconducting layer directly on a first face of the silicon substrate, the superconducting layer covering a part, but not all, of the first face of the silicon substrate, and a silicon nitride layer directly covering at least one part of the first face of the silicon substrate which is not covered by the superconducting layer.

According to a second aspect of the present disclosure, there is provided a silicon substrate, a superconducting layer directly on a first face of the silicon substrate, the superconducting layer covering a part, but not all, of the first face of the silicon substrate, the superconducting layer being comprised of a nitride, and a silicon nitride layer directly covering at least one part of the first face of the silicon substrate which is not covered by the superconducting layer.

### BRIEF DESCRIPTION OF THE DRAWINGS

FIGS. 1A-1C are cross-sectional views illustrating an example structure in accordance with at least some embodiments of the present invention;

FIG. 2A is a cross-sectional view illustrating an example structure in accordance with at least some embodiments of the present invention;

FIG. 2B is a cross-sectional view illustrating an example structure in accordance with at least some embodiments of the present invention;

FIG. 2C is a variant of the device of FIG. 2A;

FIG. 3A is a cross-sectional view illustrating an example structure in accordance with at least some embodiments of the present invention;

FIG. 3B is a cross-sectional view illustrating an example structure in accordance with at least some embodiments of the present invention;

FIG. 4A is a cross-sectional view illustrating an example structure in accordance with at least some embodiments of the present invention;

FIG. 4B is a cross-sectional view illustrating an example structure in accordance with at least some embodiments of the present invention.

FIG. 5 is a flow graph of a method in accordance with at least some embodiments of the present invention, and

FIG. 6 is a cross-sectional view illustrating example structures in accordance with at least some embodiments of the present invention.

### EMBODIMENTS

As will be disclosed herein, a nitride layer is formed on a silicon substrate based structure, such that either silicon or both silicon and superconducting surfaces are isolated from air such that formation of a native oxide layer thereon is hindered due to the presence of the nitride layer. The formation of the oxide layer may not be completely eliminated, but it is reduced in scale such that the effects of the oxide layer in terms of losses are significantly reduced. The nitride layer may be formed, for example, by bringing ionized nitrogen-containing molecules in contact with the heated silicon substrate-based structure, whereon a superconducting layer is disposed, to cover exposed parts of the silicon substrate with a silicon nitride layer. Simultaneously, a nitride layer may be formed on exposed parts of the superconducting layer. A native oxide layer may be removed from silicon or from both silicon and the superconducting layer prior to the nitriding process. The nitriding process may be done quickly after the oxide removal so that the oxide layer of at least one of the silicon or the superconducting layer does not have time to fully re-grow before the nitride layers are obtained on the exposed parts of the silicon substrate and the superconducting layer. The nitride layers may comprise at least one silicon nitride layer on the silicon. Alternatively, the nitride layer may comprise at least one silicon nitride layer on the silicon and at least one nitride layer on the superconducting layer, a nitride of the superconducting layer. By a nitride of the superconducting layer, it is meant a layer that consists of a nitrogen compound of the superconducting material it is covering. The nitride layers may be obtained, for example, by the afore-mentioned nitriding process in which the heated silicon substrate based structure is exposed to nitrogen-containing plasma.

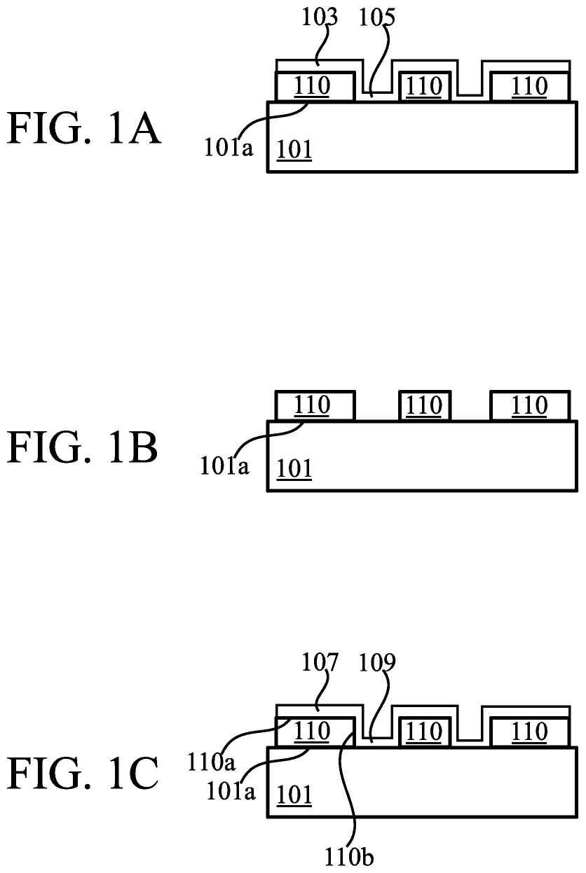

FIGS. 1A-1C illustrate an example structure in accordance with at least some embodiments of the present invention. The structure of FIG. 1A comprises a silicon substrate 101. The silicon substrate may comprise high-resistivity silicon for example. High-resistivity silicon comprises a high-purity silicon substrate characterized by a high resistivity that may be at least 2 kOhm cm, 10 kOhm cm or 20 kOhm cm, for example. The structure further comprises a superconducting layer 110. While in the side-on view of FIG. 1A the superconducting layer 110 is portrayed as three separate islands of the superconducting material, in general superconducting layer 110 may form a pattern on silicon substrate 101. Superconducting layer 110 may be a superconducting metal layer 110. The pattern may be a coplanar waveguide, or a pattern with a shape determined based on a purpose of the superconducting layer 110. Superconducting layer 110 covers a first face 101a of silicon substrate 101 in part, but not fully. The first face of silicon substrate may not need to be flat but can have more complex surface topography including, but not limited to, trenches or recesses with sloped, straight, or curved surfaces. As is schematically visible in the figure, the covered part need not be contiguous. In other words, a part of the first face 101a of silicon substrate 101 is not covered by superconducting layer 110.

Superconducting layer 110 may be directly on first face 101a of silicon substrate 101. By being directly on it is meant, that there is no deposited or grown layer of material different from silicon and the superconducting material of layer 110 between the first face 101a of silicon substrate 101 and superconducting layer 110. There may be individual atoms, molecules or small particles as impurities between first face 101a of silicon substrate 101 and superconducting layer 110, but no continuous layer of such material. In some embodiments, the superconducting layer 110 being directly on first face 101a of silicon substrate 101 does not exclude the presence of a layer of less than 1 nanometre thickness between superconducting layer 110 and silicon substrate 101. In other embodiments, there is no such less than 1 nm layer. Such a thin layer may occur unintentionally during processing. For example, a thin silicon nitride layer may form on silicon substrate 101 if a superconducting layer is deposited by reactive sputtering.

Superconducting layer 110 may be composed of a suitable superconducting metal, such as tantalum or niobium, for example, or of a superconducting compound, such as a suitable alloy, nitride, carbide or oxide, for example. The superconducting layer may be comprised of more than one material and/or more than one layer directly on one another. If superconducting layer 110 is comprised of multiple layers of different materials, one or more of these layers may also be composed of a thin intrinsically non-superconducting material to which superconductivity is induced by adjacent superconducting material at a suitable temperature. Superconducting layer 110 may be of a metal alloy, and/or different parts of this layer may be of different superconducting material. A material of superconducting layer 110 may be an elemental metal or a metallic alloy, such as niobium-titanium, germanium-niobium, or the material of layer 110 may comprise niobium nitride, niobium titanium nitride, tantalum nitride, titanium nitride, for example. By being elemental it is herein meant, that the metal comprises at least 95%, 99% or 99.9% a single chemical element. By superconducting material, it is herein meant a material, such as a metal, which is superconducting in a suitable temperature range at atmospheric pressure. For niobium this temperature range is under 9.2 Kelvin, and for tantalum it is under 4.4 Kelvin.

Superconducting devices may have their performance limited, or degraded, by one or more native oxide layers forming thereon. The herein disclosed solution also provides the benefits that it is applicable to silicon substrates and is compatible with standard silicon processing methods and fabrication tools. Furthermore, the obtained structure is applicable to different superconducting layers, and the disclosed solution enables wafer-scale processing. One way to alleviate the microwave losses from surface oxides is to change the device design so that a smaller portion of the electric field energy is stored in lossy surface oxides. This can be done, for example, by making larger devices and increasing the distance between superconducting electrodes. This approach, however, reduces integration density and, for example, in superconducting transmon qubit devices, may increase radiative losses and increase coupling to pair-breaking photons. Also, silicon trenching, backside etching, and buried electrodes may be used to reduce the effects of microwave losses from the surface oxide layers, but these approaches may require more complex processing. Nonetheless, the herein disclosed nitride layer may be used in combination with such methods, for example in combination with making the device slightly larger to reach a viability threshold in terms of microwave losses.

State-of-the-art qubits may be limited more by amorphous oxides located at material interfaces, than flaws in bulk silicon or sapphire. For silicon-based devices, one important interface is the silicon substrate-air interface. A native oxide layer of silicon forms on this surface and causes significant microwave losses in planar devices. These losses due to the silicon oxide layer are significant especially in the low-power regime that is relevant for many quantum applications.

In FIG. 1A, an oxide layer 103, 105 has formed on the illustrated device. This oxide layer comprises an oxide 103 of the superconducting material of superconducting layer 110 in parts of the oxide layer on the superconducting layer 110, and the oxide layer comprises silicon oxide 105 in parts of the oxide layer which are directly on first face 101a of silicon substrate 101. The overall oxide layer 103, 105 may be contiguous and continuous, the seams between metal oxide 103 and silicon oxide 105 may be fairly gastight in normal atmospheric conditions, since oxygen from the atmosphere causes the oxide layer 103, 105 to grow.

Advancing to FIG. 1B, the oxide layer 103, 105 has been removed from the device, for example by using a wet etchant and/or dry etchant process. The etching may use a wet etchant such as diluted hydrofluoric acid, HF or buffered hydrofluoric acid, BHF, for example. Such etching solutions remove surface oxide of silicon and hydrogen terminate exposed silicon surfaces. Hydrogen termination of silicon slows down the re-growth of the oxide layer, increasing the quality of the resulting structure in terms of less oxide being present. Re-growth of silicon oxide may also be inhibited for example by using hexamethyldisilazane, HMDS, treatment or self-assembled monolayer coatings. Alternatively, oxide layer removal may be performed by dry etching using, for example, fluorinated gases such as carbon tetrafluoride, CF₄ or sulfur hexafluoride, SF₆. The surface which in FIG. 1A is protected by the oxide layer 103, 105 may here be exposed to the atmosphere following removal of the oxide layer 103, 105, wherefore the oxide layer will begin to re-grow. The rate of re-growth may be fairly quick and the oxide layer may be re-grown fully in as little as a few days, or even minutes, depending on prevailing physical conditions and the identity of the material of layer 110. Keeping the device in vacuum or in an inert atmosphere will prevent the re-growth of the oxide layer, however maintaining the vacuum or inert atmosphere throughout the subsequent processing and characterization steps presents practical problems. Like numbering denotes like structure in FIG. 1B as in FIG. 1A.

As to the system of FIG. 1C, again like numbering denotes like structure in FIG. 1C as in FIGS. 1A and 1B. A nitride layer 107, 109 has been formed on the superconducting layer 110 and at least part of the parts of silicon substrate 101 which are exposed, that is, not covered by superconducting layer 110. This nitride layer 107, 109 comprises a nitride 107 of the superconducting layer 110 in places 107 where the nitride layer overlies superconducting layer 110, and this nitride layer 107, 109 comprises silicon nitride 109 in places where the nitride layer overlies exposed part(s) of silicon substrate 101. If superconducting layer 110 is comprised of more than one material and/or more than one layer directly on one another, nitride layer 107 may comprise different nitrides on different materials, for example on second surface 110b of superconducting layer 110. The nitride layer may comprise continuous interfaces where the nitride of superconducting layer 110 and silicon nitride meet. The nitride layer may be overall continuous and contiguous, providing a surface over the device. Nitride layer 107, 109 may be directly covering superconducting layer 110 and silicon substrate 101. Nitride 107 is on the surfaces of the superconducting layer 110 that are not directly facing or in contact with first face 101a of the silicon substrate. Besides covering the top surface 110a of the superconducting layer 110, nitride layer 107 may also cover the second surfaces 110b of the superconducting layer. These second surfaces may be straight, rounded, or curved, for example. Top surface 110a is a surface of the superconducting layer which does not directly face or contact with the silicon substrate. Second surface 110b extends from the first face 101a of the silicon substrate to top surface 110a of the superconducting layer. Nitride layer 107 may also cover superconducting layer 110 from underneath if silicon below the superconducting layer has been partially removed. Such undercuts may form when patterning the superconducting layer with isotropic etching methods, for example. In practice, a thin oxide layer may form on the the superconducting layer 110 prior to the nitriding process. Likewise, the nitride layer 107 on this surface may be practically of an oxide-nitride compound, however the effect of such a layer on performance in terms of losses may be superior to that degraded by the normal, native oxide layer.

As the nitride layer 107, 109 is formed on superconducting layer 110 and silicon substrate 101 after removal of the oxide layer 103, 105 and before this oxide layer has a chance to fully re-grow, the nitride layer effectively protects the device from the effects of the harmful oxide layer. It has been experimentally determined that the nitride layer 107, 109 causes substantially less microwave losses than native oxide layer 103, 105. For this reason, removing oxide layer 103, 105 and replacing it with nitride layer 107, 109 provides a net benefit for the superconducting device in terms of reduced microwave losses caused by interface phenomena. The nitride layer 107, 109 may be between 0.5 and 5 nanometres, nm, thick, or between 1 and 5 nm, or between 2 and 10 nm thick, for example. The nitride layer 107, 109 need not be of uniform thickness, as the nitride layer may grow to a larger thickness over superconducting layer 110 than over silicon substrate 101, or vice versa.

The nitride layer 107, 109 may be formed with nitrogen plasma exposure at elevated temperatures, for example. As nitridation is done after superconducting layer 110 has been placed on silicon substrate 101, there is no nitride layer between first face 101a of silicon substrate 101 and superconducting layer 110. A benefit of not having the nitride layer between first face 101a of silicon substrate 101 and superconducting layer 110 is that microwave losses incurred at the interface between superconducting layer 110 and silicon substrate 101 are decreased. The device of FIG. 1C is well suited for use in high-quality superconducting resonators and qubits, for example.

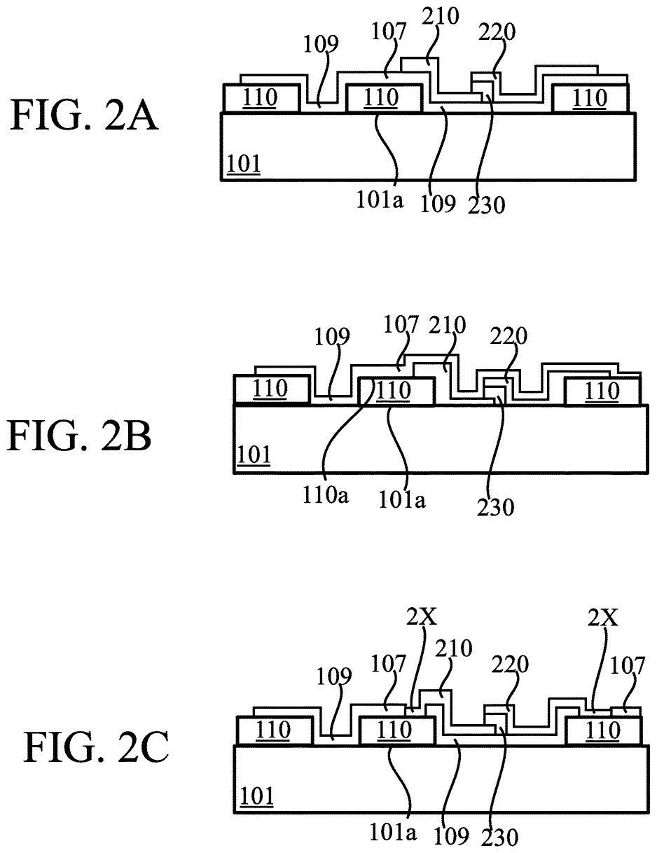

The structures of FIGS. 2A, 2B, 3A, 3B, 4A and 4B are possible applications of the process of FIGS. 1A-1C.

FIG. 2A illustrates an example structure in accordance with at least some embodiments of the present invention. Like numbering denotes like structure as in FIGS. 1A-1C. In the structure of FIG. 2A, a Josephson junction has been built on the structure of FIG. 1C, the Josephson junction 210, 220, 230 overlying parts of the nitride layer 107, 109. Nitride layer 107 is on at least part of superconducting layer 110 and nitride layer 109 is on at least some exposed part(s) of silicon substrate 101. The Josephson junction comprises two superconductors 210, 220 and a weak link 230. Weak link 230 may comprise a thin insulating tunnel barrier, a normal metal, or a narrow superconducting constriction or a semiconductor, for example. As the nitride 107, 109 layer has been placed in the device earlier, there is no hurry to build Josephson junction 210, 220, 230 since the growth of oxide layer is inhibited by nitride layer 107, 109. The structure of FIG. 2A may be used as a sub-assembly in building a superconducting qubit or resonator, for example. In a variation of this concept, nitride layer 107 and/or 109 may be partly or fully removed from areas where Josephson junction 210, 220, 230 thereon is built, for example to enhance the connection between superconducting layer 110 and the Josephson junction.

FIG. 2B illustrates an example structure in accordance with at least some embodiments of the present invention. Like numbering denotes like structure as in FIG. 2A. Here the Josephson junction 210, 220, 230 has been placed directly on silicon substrate 101 and superconducting layer 110. The nitride layer 107 is then formed on the exposed parts of superconducting layer 110, Josephson junction 210, 220, 230 and, also on at least some exposed part(s) of silicon substrate 101 as layer 109. Nitride layer 107 may comprise different nitrides, respectively on superconducting layer 110 and the superconductors 210, 220 of the Josephson junction. The structure of FIG. 2B may be used as a sub-assembly in building a superconducting qubit or resonator, for example. In FIG. 2B, nitride layer 109 covers at least some exposed part(s) of the silicon substrate, the nitride layer 107 covers at least in part the surfaces of the superconducting layer 110 that are not facing or in contact with the silicon substrate 101, and the nitride layer 107 is directly on Josephson junction 210, 220, 230, the Josephson junction 210, 220, 230 being directly on the silicon substrate 101 and the superconducting layer 110. The nitride layer 107 in FIG. 2B may comprise different nitrides, on superconducting layer 110 and metals 210, 220 of Josephson junction 210, 220, 230, respectively. Superconducting layers 210, 220 may be of the same material or two different materials. Superconducting layers 210, 220 may be comprised of more than one material and/or more than one layer directly on one another.

In some cases, the nitride layer 109, 107 is partially removed before constructing the Josephson junction and not formed on the completed Josephson junction. In such cases, the nitride layer may remain present on areas of the silicon substrate 101 and/or superconducting layer 110 which are not covered by the Josephson junction.

FIG. 2C is a variant of the device of FIG. 2A, wherein the nitride layer 107 is partially removed from superconducting layer 110, to enable enhanced electrical connections between superconducting layer 110 and the Josephson junction 210, 220, 230. The areas where this has been done are denoted 2X in FIG. 2C.

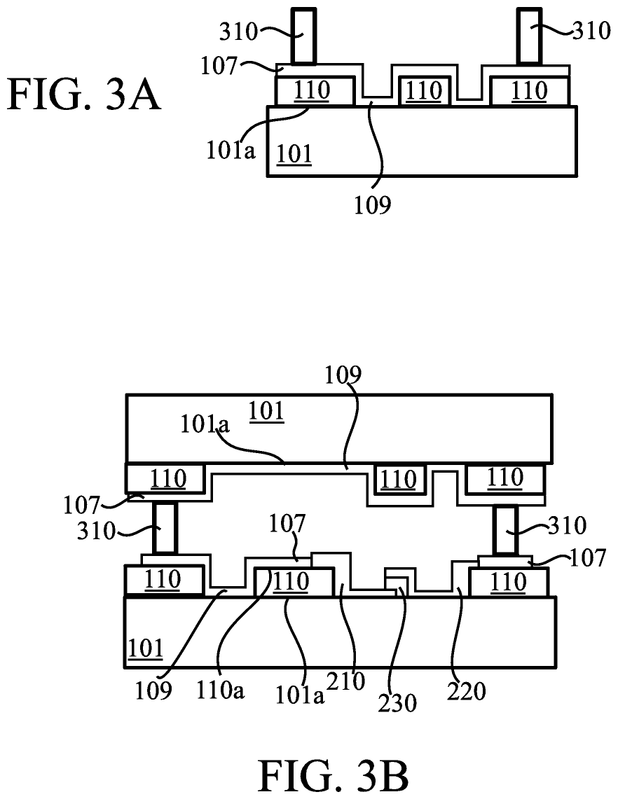

FIG. 3A illustrates an example structure in accordance with at least some embodiments of the present invention. Like numbering denotes like structure as in FIGS. 1A-1C and 2A-2B. The structure of FIG. 3A corresponds to that of FIG. 1C, onto which bump bonds 310 have been added. The bump bonds 310 may be made of indium or of solder such as tin-lead, for example. As a variation of this process, the nitride 107 may be removed from under bump bonds 210 to enhance electrical connectivity between the bump bonds 210 and superconducting layer 110. As a yet further variation, an under-bump metallization may be formed to provide a good connection for at least one bump bond 310.

FIG. 3B illustrates an example structure in accordance with at least some embodiments of the present invention. Like numbering denotes like structure as in FIGS. 1A-1C, 2A-2B and 3A. To arrive at the structure of FIG. 3B, bump bonds have been added to the structure of FIG. 2B and it is bonded with the structure of FIG. 3A using bump bonds 310. The structure of FIG. 3B is an example of a more complex functional superconducting structure which may be built using the herein disclosed nitride layer. Nitridation of both chips may be useful, since electrical fields created by devices on the lower chip may interact with surfaces of the upper chip and vice versa. Thus, nitridation of the upper chip may reduce losses of a patterned resonator on the lower chip and vice versa. In the lower substrate of FIG. 3B, the nitride layers 107 and 109 have been partially removed before constructing the Josephson junction and not formed again on the completed Josephson junction. As can be seen in the figure, the nitride layer remains present on areas of the silicon substrate 101 and/or superconducting layer 110 of the lower substrate which are not covered by the Josephson junction.

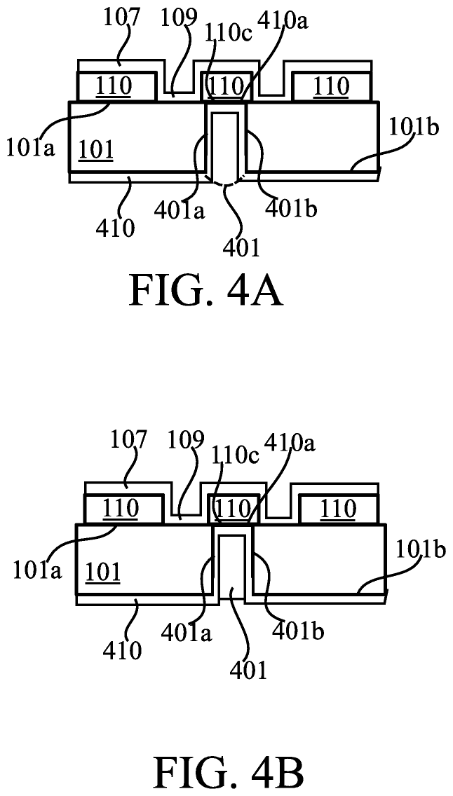

FIG. 4A illustrates an example structure in accordance with at least some embodiments of the present invention. Like numbering denotes like structure as in FIGS. 1A-1C, 2A-2B and 3A. Here a through-silicon via, TSV, 401 has been formed on the silicon substrate 101. Superconducting layer 410 covers the second face 101b of the silicon substrate 101 and sidewalls 401a and 401b of the TSV 401. TSV 401 may be a hole, such as a hole with a circular or rectangular cross section, and TSV 401 need not extend the entire length of substrate 101. FIG. 4A is thus a cross sectional view from a point where the TSV is visible. Second face 101b of silicon substrate 101 is on an opposite side of silicon substrate than first face 101a. Superconducting layer 410 is in contact with a third surface 110c of superconducting layer 110 forming an electrical interconnect between superconducting layers 410 and 110. Superconducting layer 410 may cover the whole second face 101b of the silicon substrate 101 or it may cover only a part, or parts, of it. Superconducting layer 410 may form a pattern on silicon substrate 101. The pattern may be a coplanar waveguide pattern, or a pattern with a shape determined based on a purpose of the superconducting layer 410. Superconducting layer 410 may be comprised of more than one material and/or more than one layer directly on one another. Nitride layer(s) may be formed on the exposed parts of face 101a of the silicon substrate and superconducting layer 110, as illustrated. As a variation of this process, nitride layers may be formed both on the exposed parts of faces 101a, 101b of the silicon substrate 101 and the exposed parts of superconducting layers 110 and 410. The TSV 401 may also be fully filled with superconducting material that is in contact with superconducting layer 410. The structure of FIG. 4A may be combined with structures of FIGS. 2A, 2B, and/or 3B.

FIG. 4B illustrates the device of FIG. 4A, with the TSV 401 filled with a material, rather than being a hollow.

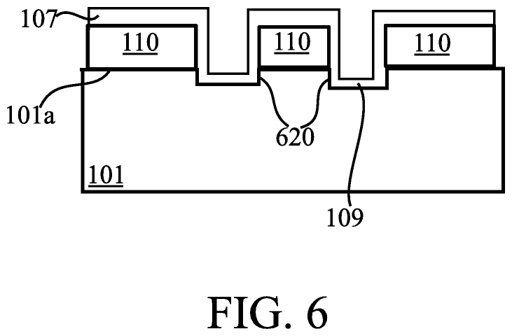

FIG. 6 illustrates an example structure in accordance with at least some embodiments of the present invention. The structure in FIG. 6 has recess sides 620 of silicon substrate 101. Such recess sides may be present also in embodiments illustrated in FIGS. 1C, 2A, 2B, 3A, 3B, 4A and 4B. Silicon may be intentionally recessed, or it may be unintentionally etched in the process of patterning the superconducting layer 110, for example. However, these recesses are also covered by a silicon nitride layer. The structure of FIG. 6 is thus one example of how superconducting layer 110 and nitride layer 107, 109 are on the first face 101a of silicon substrate 101.

Overall, technical benefits of the nitride layer may be summarized as firstly, reduced microwave losses in superconducting resonators and qubits fabricated on silicon substrates. Secondly, it is compatible with other silicon processing methods and tools, and thirdly, the process is well scalable and can be used for wafer scale quantum circuits. Finally, the herein disclosed nitride-layer devices do not require complex manufacturing steps.

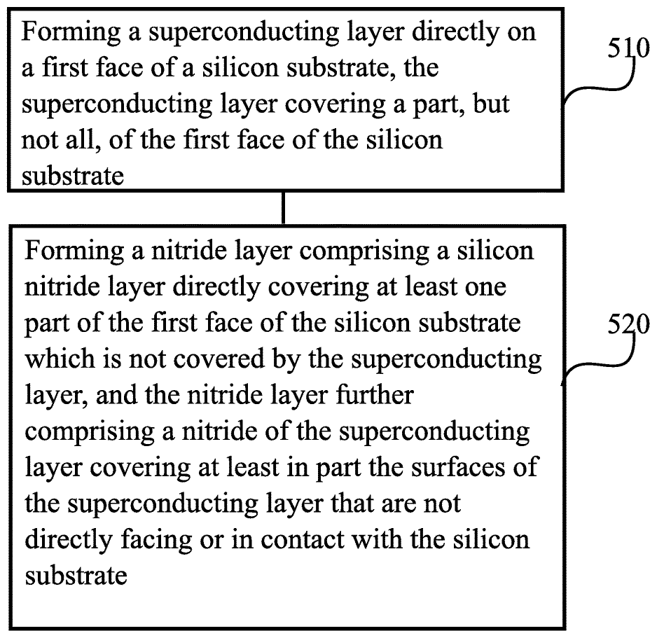

FIG. 5 is a flow graph of a method in accordance with at least some embodiments of the present invention.

Phase 510 comprises forming a superconducting layer directly on a first face of a silicon substrate, the superconducting layer covering a part, but not all, of the first face of the silicon substrate. Phase 520 comprises forming a nitride layer comprising a silicon nitride layer directly covering at least one part of the first face of the silicon substrate which is not covered by the superconducting layer, and the nitride layer further comprising a nitride of the superconducting layer covering at least in part the surfaces of the superconducting layer that are not directly facing or in contact with the silicon substrate.

It is to be understood that the embodiments of the invention disclosed are not limited to the particular structures, process steps, or materials disclosed herein, but are extended to equivalents thereof as would be recognized by those ordinarily skilled in the relevant arts. It should also be understood that terminology employed herein is used for the purpose of describing particular embodiments only and is not intended to be limiting.

Reference throughout this specification to one embodiment or an embodiment means that a particular feature, structure, or characteristic described in connection with the embodiment is included in at least one embodiment of the present invention. Thus, appearances of the phrases “in one embodiment” or “in an embodiment” in various places throughout this specification are not necessarily all referring to the same embodiment. Where reference is made to a numerical value using a term such as, for example, about or substantially, the exact numerical value is also disclosed.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary. In addition, various embodiments and example of the present invention may be referred to herein along with alternatives for the various components thereof. It is understood that such embodiments, examples, and alternatives are not to be construed as de facto equivalents of one another, but are to be considered as separate and autonomous representations of the present invention.

Furthermore, the described features, structures, or characteristics may be combined in any suitable manner in one or more embodiments. In the preceding description, numerous specific details are provided, such as examples of lengths, widths, shapes, etc., to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

While the forgoing examples are illustrative of the principles of the present invention in one or more particular applications, it will be apparent to those of ordinary skill in the art that numerous modifications in form, usage and details of implementation can be made without the exercise of inventive faculty, and without departing from the principles and concepts of the invention. Accordingly, it is not intended that the invention be limited, except as by the claims set forth below.

The verbs “to comprise” and “to include” are used in this document as open limitations that neither exclude nor require the existence of also un-recited features. The features recited in depending claims are mutually freely combinable unless otherwise explicitly stated. Furthermore, it is to be understood that the use of “a” or “an”, that is, a singular form, throughout this document does not exclude a plurality.

### INDUSTRIAL APPLICABILITY

At least some embodiments of the present invention find industrial application in manufacture and use of superconducting devices.

### ACRONYMS LIST

HF hydrofluoric acid
BHF buffered hydrofluoric acid
kOhm kilo-Ohm
nm nanometre
TSV through-silicon via
HMDS hexamethyldisilazane
CF₄ carbon tetrafluoride
SF₆ sulfur hexafluoride

### TECHNICAL CLAUSES

Clause 1. A superconducting device comprising:
a silicon substrate;
a superconducting layer directly on a first face of the silicon substrate, the superconducting layer covering a part, but not all, of the first face of the silicon substrate, the superconducting layer being comprised of a nitride;
a silicon nitride layer directly covering at least one part of the first face of the silicon substrate which is not covered by the superconducting layer,

Clause 2. The superconducting device according to Clause 1, wherein the silicon nitride layer covering the silicon substrate comprises silicon nitride.

Clause 3. The superconducting device according to Clause 2, wherein the silicon nitride layer on the silicon substrate comprises an uninterrupted layer covering at least part of the first face of the silicon substrate.

Clause 4. The superconducting device according to any of Clauses 1-3, wherein the apparatus comprises at least one of: at least one Josephson junction directly on the silicon substrate at least partly covered with a nitride layer, at least one Josephson junction at least partly on the silicon nitride layer, or at least one first Josephson junction directly on the silicon substrate with no nitride layer covering the at least one first Josephson junction.

Clause 5. The superconducting device according to any of Clauses 1-4, wherein the silicon substrate has at least one via extending through the silicon substrate and providing an electrical connection between the superconducting layer on the first face of the silicon substrate and another superconducting layer on a second face of the silicon substrate, opposite the first face of the silicon substrate.

Clause 6. The superconducting device according to any of Clauses 1-5, wherein the superconducting device further comprises a second silicon substrate with a second superconducting layer directly on a first face thereof, the second superconducting layer covering a part, but not all, of the first face of the second silicon substrate, a second silicon nitride layer covering at least one part of the first face of the second silicon substrate which is not covered by the second superconducting layer.

Clause 7. The superconducting device according to Clause 6, wherein the first silicon substrate and the second silicon substrate are coupled together using bump bonds.

Clause 8. The superconducting device according to Clause 7, wherein at least one of the bump bonds is predominantly of indium.

Clause 9. The superconducting device according to any of Clauses 1-8, wherein the superconducting layer is of niobium nitride, titanium nitride, niobium titanium nitride, or tantalum nitride.

Clause 10. The superconducting device according to any of Clauses 1-9, wherein the second silicon substrate has at least one via extending through the silicon substrate.

Clause 11. The superconducting device according to any of Clauses 1-10, wherein the superconducting device is, or comprises, a superconducting resonator or qubit.

Clause 12. The superconducting device according to Clause 11, wherein the superconducting device comprises the qubit, and the qubit is one of: a superconducting charge qubit, a superconducting flux qubit, a transmon qubit or a superconducting phase qubit.

Clause 13. The superconducting device according to Clause 11 or 12, wherein the superconducting device comprises both the resonator and the qubit.

1. A superconducting device comprising:
a silicon substrate;
a superconducting layer directly on a first face of the silicon substrate, the superconducting layer covering a part, but not all, of the first face of the silicon substrate; and
a silicon nitride layer covering at least one part of the first face of the silicon substrate which is not covered by the superconducting layer, the superconducting device being a I resonator or a qubit,
wherein the silicon nitride layer covers the at least one part of the first face of the silicon substrate directly, and a thickness of the silicon nitride layer is between 0.5 and 5 nanometres.

2. The superconducting device according to claim 1, wherein a nitride layer further covers at least in part a surface of the superconducting layer which does not directly face or contact with the silicon substrate.

3. The superconducting device according to claim 2, wherein the nitride layer further covers at least one second surface of the superconducting layer which extends from the first face of the silicon substrate to the surface of the superconducting layer which does not directly face or contact with the silicon substrate.

4. The superconducting device according to claim 2, wherein the nitride layer comprises a nitride or nitrides of a material or materials of the superconducting layer.

5. The superconducting device according to claim 4, wherein the silicon nitride layer on the silicon substrate and the nitride layer on the superconducting layer comprise an uninterrupted layer covering at least part of the first face of the silicon substrate and at least part of the superconducting layer.

6. The superconducting device according to claim 1, comprising at least one of: at least one Josephson junction directly on the silicon substrate at least partly covered with the nitride layer, at least one Josephson junction at least partly on the nitride layer, or at least one first Josephson junction directly on the silicon substrate with no nitride layer covering the at least one first Josephson junction.

7. The superconducting device according to claim 1, wherein the silicon substrate has at least one via extending through the silicon substrate and providing an electrical connection between the superconducting layer on the first face of the silicon substrate and another superconducting layer on a second face of the silicon substrate, opposite the first face of the silicon substrate.

8. The superconducting device according to claim 1, further comprising a second silicon substrate with a second superconducting layer directly on a first face thereof, the second superconducting layer covering a part, but not all, of the first face of the second silicon substrate, a second silicon nitride layer covering at least one part of the first face of the second silicon substrate which is not covered by the second superconducting layer.

9. The superconducting device according to claim 8, wherein a second nitride layer of the second superconducting layer further covers at least in part surfaces of the second superconducting layer that are not directly facing or in contact with the second silicon substrate.

10. The superconducting device according to claim 8, wherein the first silicon substrate and the second silicon substrate are coupled together using bump bonds.

11. The superconducting device according to claim 10, wherein at least one of the bump bonds is predominantly of indium.

12. The superconducting device according to claim 11, wherein the superconducting layer is niobium or tantalum.

13. The superconducting device according to claim 8, wherein the second silicon substrate has at least one via extending through the silicon substrate.

14. The superconducting device according to claim 1, wherein the superconducting device comprises the qubit, and the qubit is one of: a superconducting charge qubit, a superconducting flux qubit, a transmon qubit or a superconducting phase qubit.

15. The superconducting device according to claim 1, wherein the superconducting device comprises both the resonator and the qubit.

16. The superconducting device according to claim 1, wherein the superconducting layer is comprised of a nitride.
